(19) United States
(12) Patent Application Publication
(10) Pub. No.: US 2001/0043703 A1
(43) Pub. Date: Nov. 22, 2001

(54) Box-like enclosure for spatially orientable speakers

(75) Inventor: Maurizio Montanari, Casalecchio Di Reno (IT)

Correspondence Address: MODIANO & ASSOCIATI, Via Meravigli, 16, MILANO, 20123, IT

(73) Assignee: ELETTRONICA MONTARBO S.R.L.

(21) Appl. No.: 09/852,347

(22) Filed: May 11, 2001

(30) Foreign Application Priority Data
May 16, 2000 (IT) B02000U000073

(51) Int. Cl. H04R 1/02; H05K 5/00; H04R 9/06

(52) U.S. Cl. 381/87; 381/336; 381/386; 381/387; 381/395; 181/150

(57) ABSTRACT

A box-like enclosure for spatially orientable speakers, having a plurality of engagement elements formed during the molding of the enclosure in its peripheral region and engaged by ends of anchoring cables in order to allow any spatial orientation of the enclosure.

### BACKGROUND OF THE INVENTION

The present invention relates to a box-like enclosure for spatially orientable speakers.

It is known that speaker cases or boxes are currently commercially available which have various kinds of element for engaging the ends of anchoring cables in order to allow the spatial placement of the speakers, particularly in showrooms or outdoor.

These kinds of element are usually constituted by one or more elements, which are rigidly connected to each other and then associated with one end of the suspension cables. They further provide for the addition, to the suspension box, of at least one element which is fixed by means of screws to the outer surface of said box.

This assembly often requires additional machining in order to form the seats in the box which accommodate said elements.

In particular, it has been found that the engagement elements that are currently used constitute a problem, since often damages at the frame region surrounding the engagement element occurs, owing to the stresses to which such region is subjected during suspension generated by the tension in the anchoring cables.

Moreover, the machining and the consequent additional assembly of the elements increase the times for manufacturing the speaker, thereby affecting the final cost of the product.

### SUMMARY OF THE INVENTION

The aim of the present invention is to obviate the cited drawbacks by providing a box-like enclosure for spatially orientable speakers which solves the above noted problems, eliminating the need for additional mechanical elements and additional assembly operations.

Within this aim, an object of the present invention is to provide a structure which is simple, relatively easy to provide in practice, safe in use, effective in operation and relatively low in cost.

This aim and these and other objects which will become better apparent form the following description are achieved by the present box-like enclosure for spatially orientable speakers, characterized in that it has a plurality of engagement elements formed by molding said enclosure in its peripheral region, said engagement elements being engaged by ends of anchoring cables in order to allow any spatial orientation of said enclosure.

### BRIEF DESCRIPTION OF THE DRAWINGS

Further characteristics and advantages of the present invention will become better apparent from the detailed description of preferred but not exclusive embodiments of a box-like enclosure for spatially orientable speakers, according to the invention, illustrated only by way of non-limitative example in the accompanying drawings, wherein:

FIG. 1 is a perspective view of a first embodiment of the enclosure;

FIG. 2 is a front view thereof;

FIG. 3 is a top view thereof;

FIGS. 4, 5, 6 and 7 are views of operating positions of the box-like enclosure of FIG. 1;

FIGS. 8, 9 and 10 are a perspective view, a plan view, and a front view, respectively, of a second embodiment of said enclosure;

FIGS. 11, 12 and 13 are a perspective view, a plan view and a front view, respectively, of a third embodiment of said enclosure;

FIGS. 14, 15 and 16 are a perspective view, a plan view and a front view, respectively, of a fourth embodiment of said enclosure;

FIGS. 17, 18 and 19 are a perspective view, a plan view and a front view, respectively, of a fifth embodiment of said enclosure;

FIGS. 20 and 20a are views of a sixth embodiment of said box-like enclosure, in which said engagement elements are made of a different material with respect to said enclosure and are intimately integrated therein during molding;

FIG. 21 is an enlarged-scale view of said engagement element, intimately integrated at one of the corners of said enclosure;

FIG. 22 is a sectional view, taken along the plane XII-XII of FIG. 21;

FIGS. 23 and 24 are a perspective view and an exploded front view, respectively, of a seventh embodiment of said enclosure.

### DESCRIPTION OF THE PREFERRED EMBODIMENTS

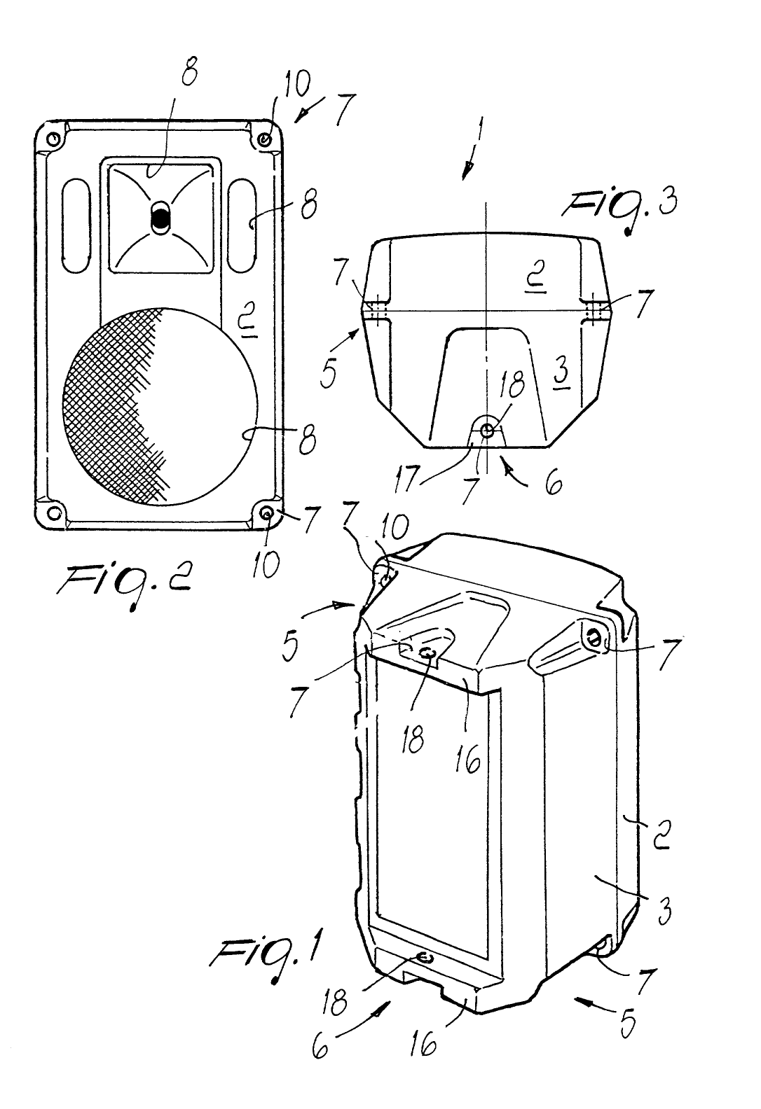

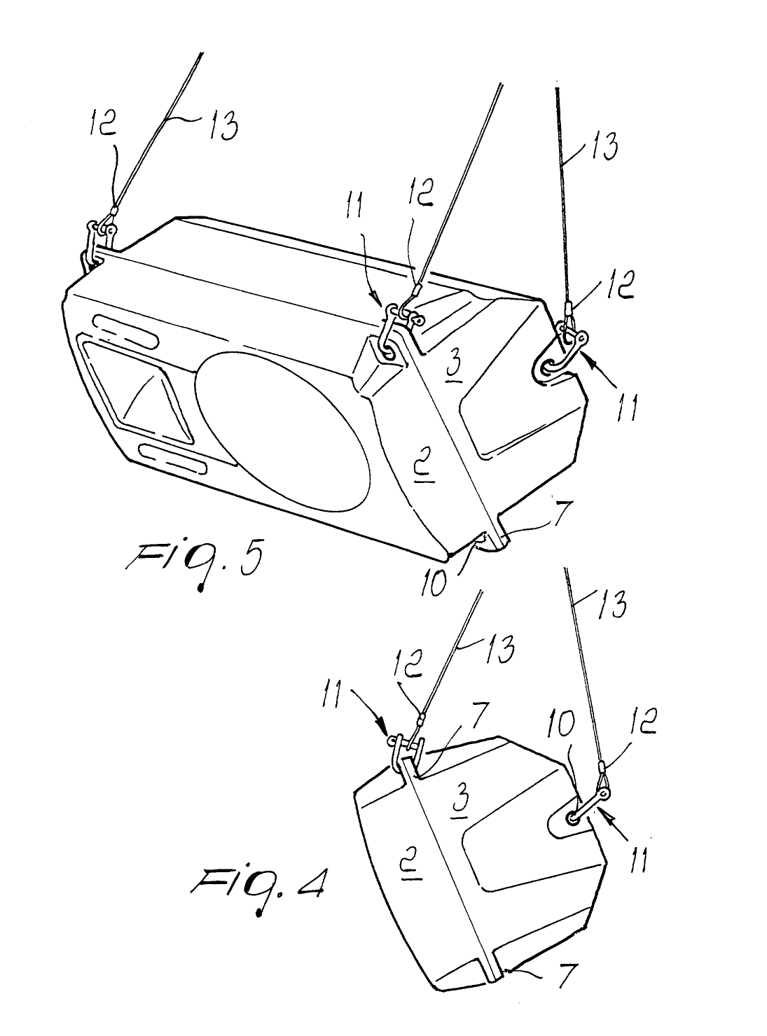

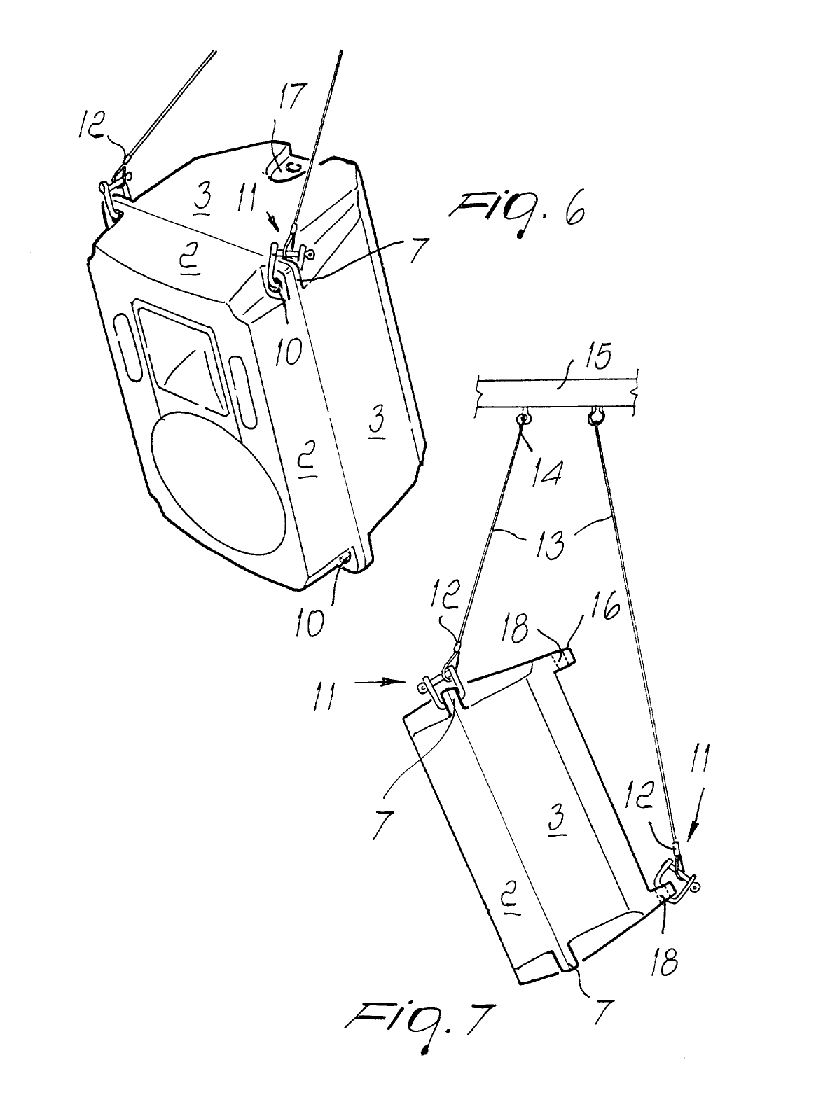

With reference to the figures, the reference numeral 1 generally designates a box-like enclosure for speakers according to a first embodiment of the invention. The box-like enclosure 1 made of plastics is substantially a prism-shaped monolithic body formed during molding and is internally provided with a cavity in which acoustic means are accommodated. The box-like enclosure 1 further defines a front portion 2 and a rear portion 3. The box-like enclosure 1 has engagement elements 7 on its outer peripheral region, at the lateral sharp edges 5 and at the rear sharp edges 6, as shown in FIGS. 1 to 7; said engagement elements are formed during molding. The front portion 2 is provided with openings 8 which are formed at the output cone, by way of which the acoustic means radiate sound.

The engagement elements 7 at the lateral sharp edges 5 form lugs which are crossed by holes 10. The holes 10 can be engaged with hooks 11, which are constituted for example by shackles, which are connected to one end 12 of anchoring cables 13 whose other end 14 is coupled to fixed parts 15. Likewise, the engagement elements 7, at the rear sharp edges 6, form a protrusion 16 which has, in its central region, a recess 17 which is crossed by a hole 18. The hole 18, like the hole 10, can be engagd by means of the hooks 11.

It is also possible to form engagement elements 7 during molding on each face of the box-like enclosure 1.

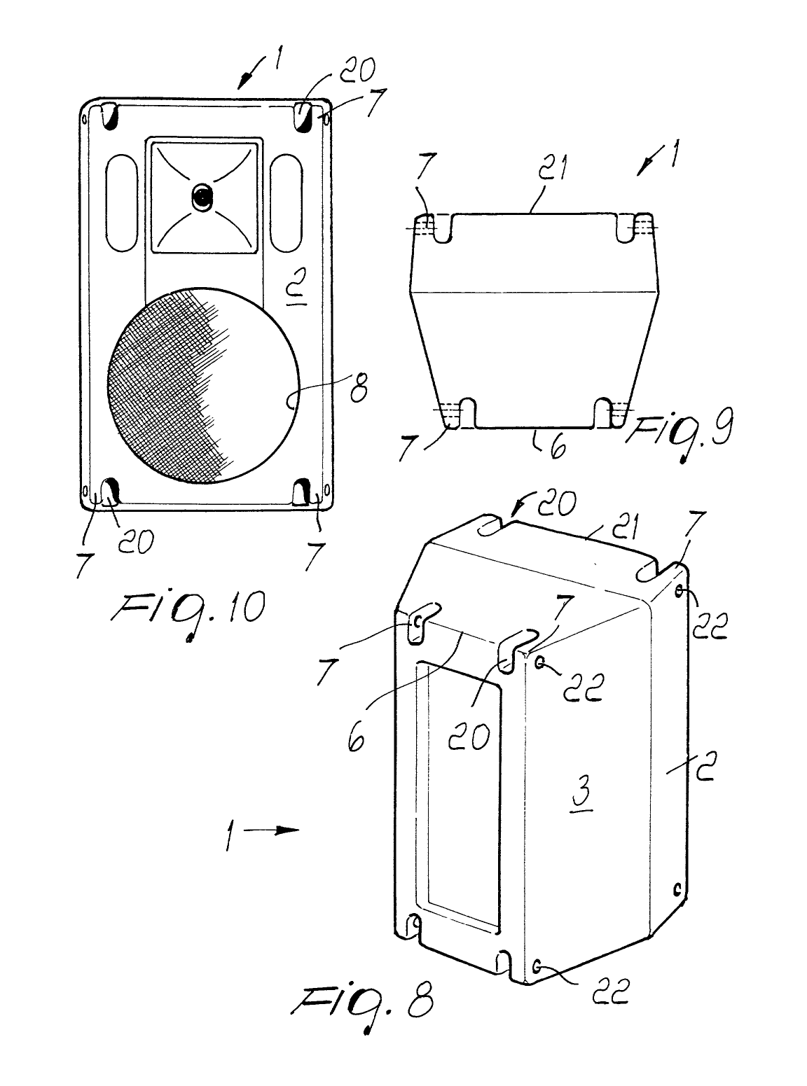

A second embodiment of the box-like enclosure 1 for speakers, according to the invention, is shown in FIGS. 8 to 10. In this second embodiment, the engagement elements 7 are formed by hollows 20 provided during molding at the rear sharp edges 6 and at the front sharp edges 21. The engagement elements 7, together with the hollows 20, form lugs which are crossed by holes 22 which are engaged by the hooks 11.

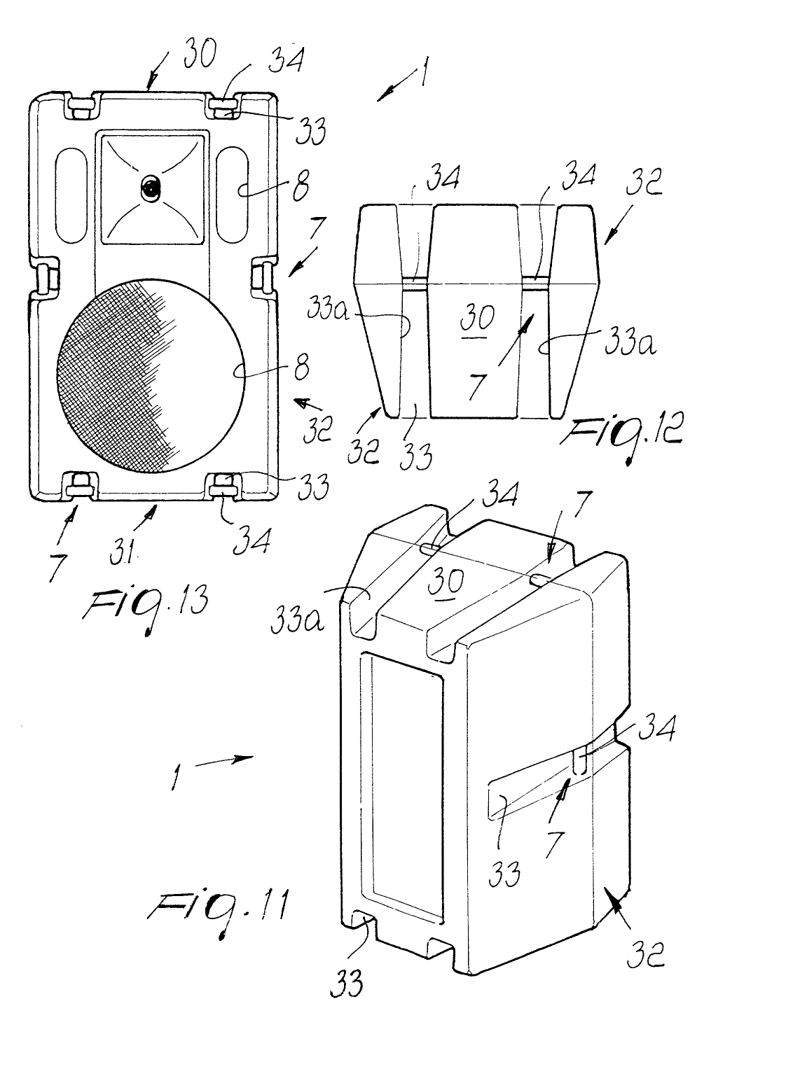

A third embodiment of the box-like enclosure 1 according to the invention is shown in FIGS. 11 to 13. In this embodiment, two substantially parallel slots 33 are formed by molding at the upper face 30 and at the lower face 31 and run along the entire length of said faces 30 and 31; at the central region of the lateral faces 32, another slot 33 is formed which runs along the entire length of each one of the faces 32. Proximate to the central region of each one of the slots 33 there is a bridge 34 which connects the walls 33a of the slot 33 so as to form respective engagement elements 7 which are engaged by the hooks 11 in order to allow the optimum spatial arrangement of the box-like enclosure 1.

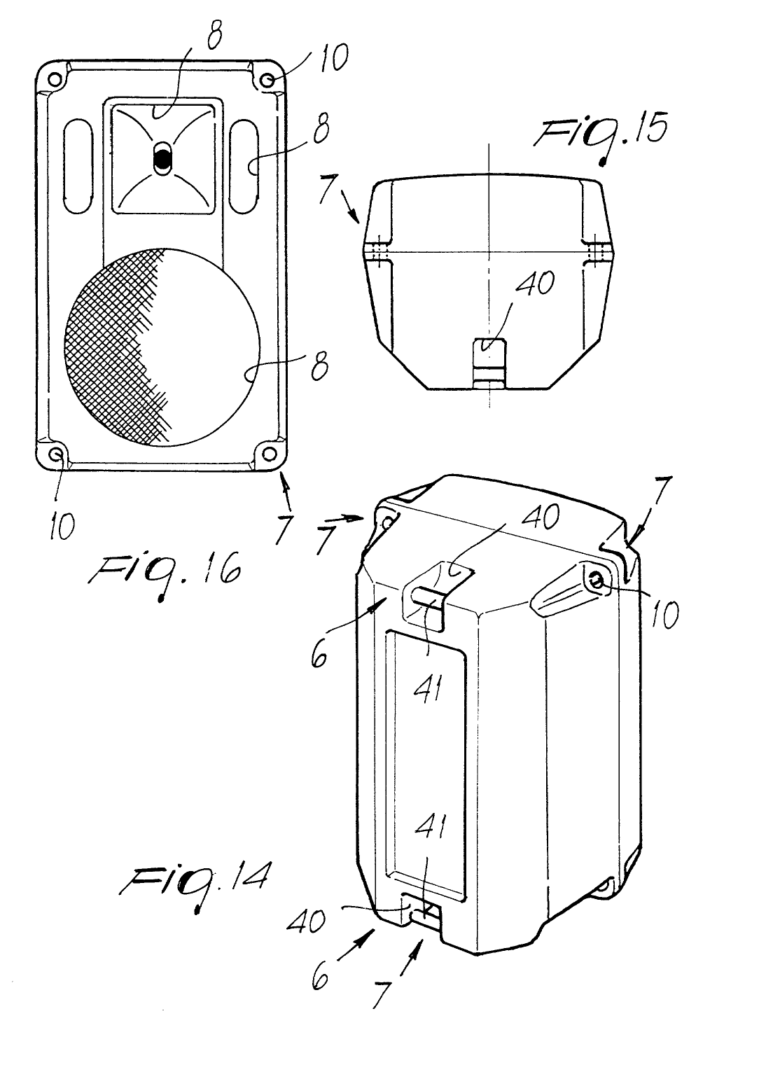

A fourth embodiment of the box-like enclosure 1 is illustrated in FIGS. 14 to 16. This embodiment differs from the one shown in FIGS. 1 to 7 in that at the central region of the rear sharp edges 6 the engagement elements 7 are formed, during molding, by indentations 40 whose walls are joined by rods 41.

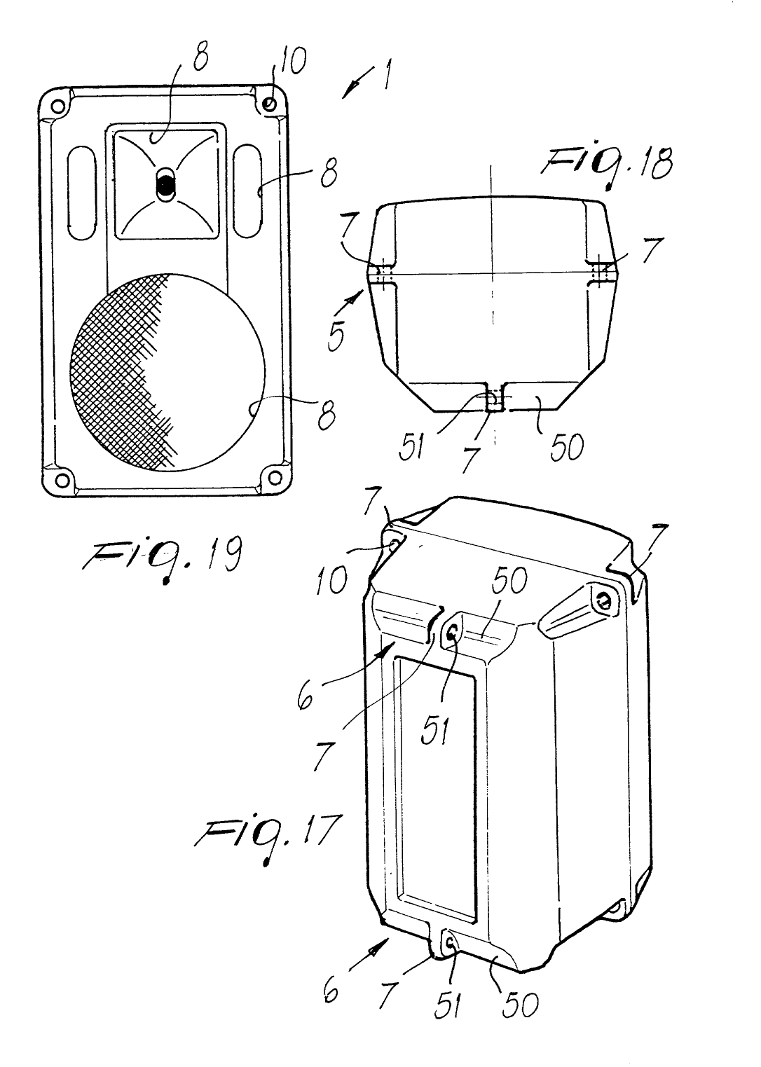

A fifth embodiment of the invention is illustrated, in FIGS. 17 to 19. In this embodiment there is, at the rear sharp edge 6, a recess 50 from which there protrudes, proximate to the central region, the engagement element 7, which forms a lug provided with a hole 51 meant to be engaged by the hooks 11.

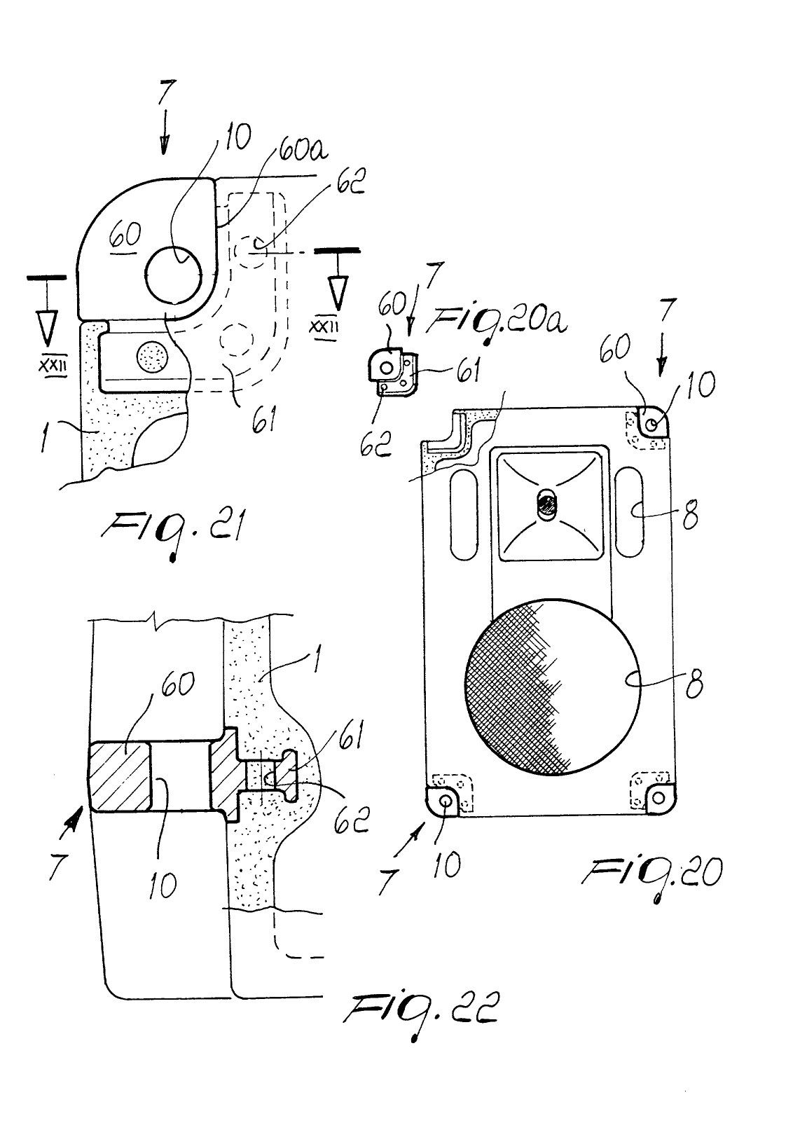

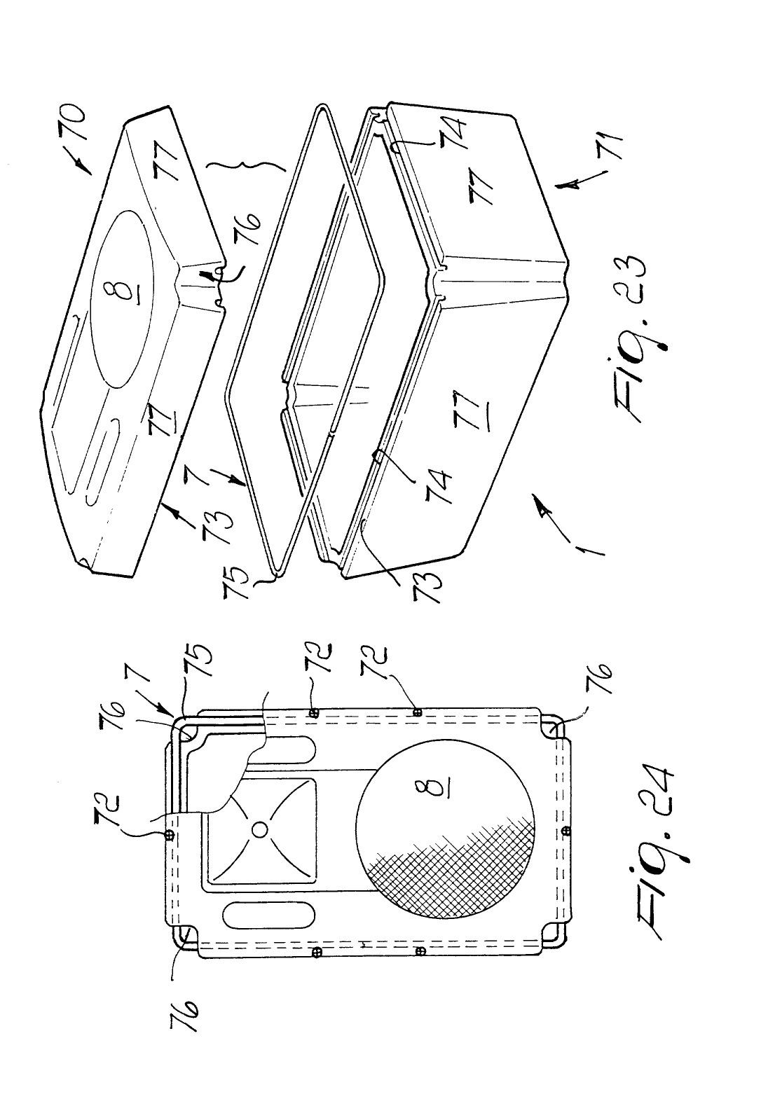

A sixth embodiment of the invention is illustrated in FIGS. 20 to 22. In this embodiment, the engagement elements 7 consist of lugs 60, preferably made of metallic material, which are crossed centrally by a hole 10 which is meant to engage the hooks 11; a lamina 61 provided with holes 62 is rigidly coupled to each one of the lugs 60, along the peripheral portion 60a; during the molding of the box-like enclosure 1, said lamina is intimately integrated in the sharp edges.

A seventh embodiment is shown in FIGS. 23 and 24. In this embodiment, the box-like enclosure 1 comprises a front cover 70 and a rear cover 71 which, thanks to connecting means constituted by screws 72, are coupled along front complementary peripheral edges 73, thus determining the prism-like shape of the box-like enclosure 1. The peripheral edges 73 are provided with perimetric seats which are constituted by slots 74 which accommodate the engagement elements 7. The engagement elements 7 consist of a frame protruding with the rounded portions 75 thereof, from recesses 76 formed on the converging regions of the adjacent lateral faces 77. Said rounded portions are meant to engage the hooks 11.

In practical operation, the engagement elements 7 are engaged by the anchoring cables 13 so as to allow the optimum spatial orientation of the box-like enclosure 1 for speakers.

An advantage of the present invention is that the engagement elements are formed during molding according to the most disparate requirements, so as to meet the various possibilities of positioning and suspension in space.

It has thus been shown that the invention achieves the intended aim and objects.

The invention thus conceived is susceptible of numerous modifications and variations, all of which are within the scope of the appended claims.

All the details may further be replaced with other technically equivalent elements.

In practice, the materials used, as well as the shapes and the dimensions, may be any according to requirements without thereby abandoning the scope of the protection of the appended claims.

The disclosures in Italian Utility Model Application No. B02000U000073 from which this application claims priority are incorporated herein by reference.

What is claimed is:

1. A box-like enclosure for spatially orientable speakers, comprising: a molded body; a plurality of engagement elements formed at a peripheral region of said body during molding thereof; and anchoring cables for engaging with a first end thereof said engagement elements in order to allow different spatial orientations of the enclosure.

2. A box-like enclosure for spatially orientable speakers, comprising: a molded body; a plurality of engagement elements which are intimately integrated in a peripheral region of said body during molding thereof; and anchoring cables for engaging with a first end thereof said engagement elements so as to allow different spatial orientations of the enclosure.

3. A box-like enclosure for spatially orientable speakers, comprising: a front cover and a rear cover which are coupled to each other in opposition, along front complementary peripheral edges thereof, connecting means for connecting said front and rear covers; recesses arranged at lateral faces of said front and rear covers; perimetric seats provided at said peripheral edges; engagement elements fixedly accommodated in said seats through coupling of said front and rear covers so as to protrude from said recesses; and anchoring cables for engaging with a first end thereof said engagement elements at said recesses, so as to allow different spatial orientations of the enclosure.

4. The enclosure of claim 3, wherein said perimetric seats consist of a slot formed along said peripheral edges.

5. The enclosure of claim 4, wherein said engagement elements consist of a frame which is accommodated in said slot.

6. The enclosure of claim 1, wherein each said first end of said cables is provided with a respective hook, which engages said engagement elements.

7. The enclosure of claim 6, wherein said cables are connectable at a second end thereof to environmental fixed supporting parts.

8. The enclosure of claim 1, wherein said body is monolithic and produced by molding so as to form an internal cavity for accommodating acoustic means.

9. The enclosure of claim 8, constituted by a front cover and a rear cover.

10. The enclosure of claim 9, wherein said front cover is provided with openings for sound radiation.

11. The enclosure of claim 2, wherein said engagement elements are made of metallic material.

12. The enclosure of claim 1, wherein said enclosure is made of any of a plastic and a metallic material.
